(19) United States
(12) Patent Application Publication
(10) Pub. No.: US 2026/0338855 A1
(43) Pub. Date: Oct. 29, 2026

(54) PARALLEL HOT SWAP CONTROLLER CHIP FAULT PROCESSING APPARATUS AND METHOD, AND DEVICE AND MEDIUM

(71) Applicant: SUZHOU METABRAIN INTELLIGENT TECHNOLOGY CO., LTD., Suzhou, Jiangsu (CN)

(72) Inventors: Siheng LUO, Suzhou, Jiangsu (CN); Cai KONG, Suzhou, Jiangsu (CN)

(73) Assignee: SUZHOU METABRAIN INTELLIGENT TECHNOLOGY CO., LTD., Suzhou, Jiangsu (CN)

(21) Appl. No.: 18/995,816

(22) PCT Filed: Jun. 16, 2023
(86) PCT No.: PCT/CN2023/100842

§ 371 Date: Jan. 16, 2025

(30) Foreign Application Priority Data
Nov. 10, 2022 (CN) 202211404113.9

(51) Int. Cl. G01R 31/28; H02H 1/00; H02H 3/04; H02H 3/20; H02H 5/04; H02J 1/00

(52) U.S. Cl. CPC G01R 31/2851; H02H 1/0007; H02H 3/042; H02H 3/202; H02H 5/041; H02J 1/001

(57) ABSTRACT

The present disclosure relates to the field of circuit designs, and in particular, to a parallel hot swap controller chip fault processing apparatus and method, and a device and a non-transitory readable storage medium. The apparatus comprises: a plurality of parallel hot swap controller chips, wherein each hot swap controller chip has several preset fault state signals; a plurality of conversion circuits, the conversion circuits corresponding to the hot swap controller chip on a one-to-one basis, and each of the conversion circuits being configured convert the plurality of preset fault state signals into a fault alert signal and outputting same; and a controller, which is configured to analyze the fault alert signal outputted by each of the conversion circuit, so as to determine a faulty hot swap controller chip and the fault type of the hot swap controller chip.

### CROSS-REFERENCE TO RELATED APPLICATION

The present application is a National Stage Application of PCT International Application No.: PCT/CN2023/100842 filed on Jun. 16, 2023, which claims priority to Chinese Patent Application 202211404113.9, filed in the China National Intellectual Property Administration on Nov. 10, 2022, the disclosure of which is incorporated herein by reference in its entirety.

### TECHNICAL FIELD

The present disclosure relates to the field of circuit designs, and in particular, to an apparatus of processing a fault of a parallel hot swap controller chip and method, and a device and a non-transitory readable storage medium.

### BACKGROUND

In recent years, with the continuous rise of cloud computing technology, Internet traffic amount increases continuously, which imposes higher requirement on the data processing capability and storage capacity of machine room servers. As a unit-cabinet system in a traditional machine room, it is required that server computing nodes deployed inside a cabinet have higher and higher data processing capability and higher and higher deployment density. Along with the increase of Internet user services, network data throughput also becomes larger and larger, and a data center machine room has higher and higher deployment density of servers. In order to increase the deployment density while enhancing the maintainability, servers are usually deployed in the cabinet in the form of a single node, and a single-node server is directly plugged into a power source BUSBAR by a POWER CLIP connector for power acquisition.

The server, as a basic data processing unit of the data center, has an increasingly larger workload. Especially a CPU (Central Processing Unit) chip inside the server has an increasingly larger working load current, and a working current of a single CPU is as high as 100 to 200 A. Therefore, the current of a power supply input end of a single server node is increasingly larger, and a current passing requirement of a hot swap line of a corresponding input end is increasingly higher. Therefore, a hot swap unit often uses a plurality of Hot Swap Controller (HSC) chips connected in parallel to meet large-current application requirements. In practical applications, the plurality of HSCs being connected in parallel has the following risks: First, when a certain one or several HSCs among them trigger single-line Over Current Protection (OCP for short), Short Current Protection (SCP for short), Over Temperature Protection (OTP for short), and Over Voltage Protection (OVP for short), the entire hot swap line will be powered down, such that the problem at the location where fault occurs cannot be determined quickly and accurately. Secondly, when the plurality of HSCs are used in parallel, due to the individual differences of the HSC chips and the differences of LAYOUT, the magnitudes of currents flowing through the HSC chips are different, and when the differences become larger, the problem of unbalanced HSC currents will occur. Under high-load working conditions for a long time, a breakdown failure easily occurs, which causes a risk that an HSC chip is short-circuited to the ground and is powered down or causes a board-burning risk. This affects normal running of customer services, and also brings about hidden dangers to fire safety of the data center machine room due to board burning. Moreover, once the board-burning problem occurs, research and development engineers often invest resources to perform location analysis on the problem on site, and the board burning may cause great difficulty in reappearance of the problem site, and locating of the reason for the board burning also has great difficulty.

FIG. 1 is a schematic structural diagram of a conventional application scenario in which a plurality of HSCs are connected in parallel. When a plurality of HSC chips are connected in parallel, an input end Vin is converged on a POWER CLIP connector to acquire power from a BUSBAR, and an output end Vout is converged together to supply power to a load. In addition, a Baseboard Management Controller (BMC for short) on a main board of a server node samples a voltage of the output end of the HSCs to detect an anomalous state of an output voltage. However, such a processing method has the following disadvantages: on one hand, when certain one or more HSCs trigger single-line OCP, SCP, OTP and OVP, it is difficult to locate the fault. On the other hand, when unbalanced HSC currents occur due to the individual differences of the HSC chips and the differences of line LAYOUT, automatic protection cannot be performed, and thus the safety is poor, and there is an urgent need for improvement.

### SUMMARY

In view of this, regarding the technical problems above, it is necessary to provide an apparatus of processing a fault of a parallel hot swap controller chip and method, and a device and a non-transitory readable storage medium.

According to a first aspect of some embodiments of the present disclosure, provided is an apparatus of processing a fault of a parallel hot swap controller chip, comprising:
a plurality of parallel hot swap controller chips, each of the hot swap controller chips having a plurality of preset fault state signals;
a plurality of conversion circuits, each the conversion circuits of the corresponding to the hot swap controller chips on a one-to-one basis, and each of the conversion circuits being configured to convert plurality of the preset fault state signals into a fault alert signal and outputting the fault alert signal; and
a controller, configured to analyze the fault alert signal outputted by each of the conversion circuits to determine a faulty hot swap controller chip and a fault type of the faulty hot swap controller chip.

In some embodiments, the number of the parallel hot swap controller chips is determined according to a maximum current value, and a model of each of the hot swap controller chips is determined according to the maximum current value; the maximum current value is a current value, 80% of which is equal to a current value corresponding to a total power consumption of a server system.

In some embodiments, the conversion circuit comprises: a first switch transistor, a second switch transistor, a third switch transistor, a fourth switch transistor, a first resistor, a second resistor, a third resistor, a fourth resistor and a pull-up resistor; resistance values of the first resistor, the second resistor, the third resistor and the fourth resistor are all different;
the first switch transistor and the first resistor are connected in series to form a first branch circuit, the second switch transistor and the second resistor are connected in series to form a second branch circuit, the third switch transistor and the third resistor are connected in series to form a third branch circuit, and the fourth switch transistor and the fourth resistor are connected in series to form a fourth branch circuit; one end of the pull-up resistor is connected to a power source, the first branch circuit, the second branch circuit, the third branch circuit and the fourth branch circuit are connected in parallel between the other end of the pull-up resistor and the ground, and the first switch transistor, the second switch transistor, the third switch transistor and the fourth switch transistor are all grounded, and the fault alert signal is a voltage value at the other end of the pull-up resistor;
the preset fault state signals comprise an over current protection signal, an over temperature protection signal, a short current protection signal and an over voltage protection signal, wherein the over current protection signal is configured to drive the first switch transistor to be turned on or off, the over temperature protection signal is configured to drive the second switch transistor to be turned on or off, the short current protection signal is configured to drive the third switch transistor to be turned on or off, and the over voltage protection signal is configured to drive the fourth switch transistor to be turned on or off; and at most one of the first switch transistor, the second switch transistor, the third switch transistor and the fourth switch transistor is turned on at the same moment.

In some embodiments, the conversion circuit comprises: a first switch transistor, a second switch transistor, a third switch transistor, a fourth switch transistor, a first resistor, a second resistor, a third resistor, a fourth resistor, a fifth resistor, a sixth resistor, a seventh resistor and a pull-up resistor; resistance values of the first resistor, the second resistor, the third resistor, the fourth resistor, the fifth resistor, the sixth resistor, the seventh resistor and the pull-up resistor are all the same;
the first switch transistor and the first resistor are connected in series to form a first branch circuit, the second switch transistor and the second resistor are connected in series to form a second branch circuit, the third switch transistor and the third resistor are connected in series to form a third branch circuit, and the fourth switch transistor and the fourth resistor are connected in series to form a fourth branch circuit; one end of the pull-up resistor is connected to a power source, and the first branch circuit, the second branch circuit, the third branch circuit and the fourth branch circuit are connected in parallel between the other end of the pull-up resistor and the ground, the first switch transistor, the second switch transistor, the third switch transistor and the fourth switch transistor are all grounded, the fifth resistor is connected in series between the first resistor and the second resistor, the sixth resistor is connected in series between the second resistor and the third resistor, the seventh resistor is connected in series between the third resistor and the fourth resistor, and the fault alert signal is a voltage value at the other end of the pull-up resistor;
the preset fault state signals comprise an over current protection signal, an over temperature protection signal, a short current protection signal and an over voltage protection signal, the over current protection signal is configured to drive the first switch transistor to be turned on or off, the over temperature protection signal is configured to drive the second switch transistor to be turned on or off, the short current protection signal is configured to drive the third switch transistor to be turned on or off, and the over voltage protection signal is configured to drive the fourth switch transistor to be turned on or off; and t, at most one of the first switch transistor, the second switch transistor, the third switch transistor and the fourth switch transistor is turned on at the same moment.

In some embodiments, the controller is further configured to:
in response to the fault alert signal outputted by a conversion circuit and being equal to half of a power source voltage, confirm that a hot swap controller chip corresponding to the conversion circuit outputting the fault alert signal being equal to half of the power source voltage has a fault, and the fault type is over current protection of the hot swap controller chip;
in response to the fault alert signal outputted by a conversion circuit and being equal to two thirds of the power source voltage, confirm that a hot swap controller chip corresponding to the conversion circuit outputting the fault alert signal being equal to two thirds of the power source voltage has a fault, and the fault type is over temperature protection of the hot swap controller chip;
in response to the fault alert signal outputted by a conversion circuit and being equal to three quarters of the power source voltage, confirm that a hot swap controller chip corresponding to the conversion circuit outputting the fault alert signal being equal to three quarters of the power source voltage has a fault, and the fault type is short current protection of the hot swap controller chip;
in response to the fault alert signal outputted by a conversion circuit and being equal to four fifths of the power source voltage, confirm that a hot swap controller chip corresponding to the conversion circuit outputting the fault alert signal being equal to four fifths of the power source voltage has a fault, and the fault type is over voltage protection of the hot swap controller chip; and
in response to the fault alert signal outputted by a conversion circuit and being equal to zero, confirm that a hot swap controller chip corresponding to the conversion circuit outputting the fault alert signal being equal to zero has no fault.

In some embodiments, each of the hot swap controller chips further has a current detection signal, and the controller is further configured to collect the current detection signal of each of the hot swap controller chips, process the collected current detection signal, and then generate a current balance alert signal and a current balance control signal according to a preset decision rule; and
the apparatus further comprises an AND gate, a first input end of the AND gate is connected to a power-on signal, a second input end of the AND gate is connected to the current balance control signal, and an output end of the AND gate is connected to an enable signal pin of each of the hot swap controller chips.

In some embodiments, the AND gate is configured to turn off, in a case where the received current balance control signal is at a low level, a hot swap controller chip corresponding to the current balance control signal.

In some embodiments, the controller is further configured to:
calculate an average value of all collected current detection signals;
in response to the current detection signal of any one of the hot swap controller chips being less than 0.6 times the average value or greater than 1.6 times the average value, output the current balance alert signal indicating that an alert is required, and output the current balance control signal for turning off hot swap controller chips;
in response to the current detection signal of each of the hot swap controller chips being greater than or equal to 0.6 times the average value and less than or equal to 1.6 times the average value, and the current detection signal of any one of the hot swap controller chip being greater than or equal to 0.6 times the average value and less than 0.9 times the average value, output the current balance alert signal indicating that an alert is required, and output the current balance control signal for not turning off the hot swap controller chips;
in response to the current detection signal of each of the hot swap controller chips being greater than or equal to 0.6 times the average value and less than or equal to 1.6 times the average value, and the current detection signal of any one of the hot swap controller chips being greater than 1.1 times the average value and less than or equal to 1.6 times the average value, output the current balance alert signal indicating that an alert is required, and output the current balance control signal for not turning off the hot swap controller chips; and
in response to the current detection signals of each of the hot swap controller chips being greater than or equal to 0.9 times the average value and less than or equal to 1.1 times the average value, output the current balance alert signal indicating that an alert is not required, and output the current balance control signal for not turning off the hot swap controller chips.

In some embodiments, the controller is a baseboard management controller.

In some embodiments, a current detection signal pin of each of the hot swap controller chips is connected with an analog-to-digital conversion input/output pin of the baseboard management controller, and an alert signal pin of each of the hot swap controller chips is connected with an analog-to-digital conversion input/output pin of the baseboard management controller; the current detection signal pin is configured to output a current detection signal of the hot swap controller chip corresponding to the current detection signal pin, and the alert signal pin is configured to output an alert signal of the hot swap controller chip corresponding to the alert signal pin.

According to a second aspect of some embodiments of the present disclosure, provided is an method of processing a fault of a parallel hot swap controller chip, comprising:
a plurality of hot swap controller chips are connected in parallel, each of the hot swap controller chips having a plurality of preset fault state signals;
by each of conversion circuits, the preset fault state signals are converted into a fault alert signal, wherein the conversion circuits correspond to the hot swap controller chips on a one-to-one basis; and
the fault alert signal outputted by each of the conversion circuit is analyzed by a controller, to determine a faulty hot swap controller chip and fault type of the faulty hot swap controller chip.

In some embodiments, the conversion circuit comprises: a first switch transistor, a second switch transistor, a third switch transistor, a fourth switch transistor, a first resistor, a second resistor, a third resistor, a fourth resistor and a pull-up resistor; resistance values of the first resistor, the second resistor, the third resistor and the fourth resistor are all different;
the first switch transistor and the first resistor are connected in series to form a first branch circuit, the second switch transistor and the second resistor are connected in series to form a second branch circuit, the third switch transistor and the third resistor are connected in series to form a third branch circuit, and the fourth switch transistor and the fourth resistor are connected in series to form a fourth branch circuit; one end of the pull-up resistor is connected to a power source, the first branch circuit, the second branch circuit, the third branch circuit and the fourth branch circuit are connected in parallel between the other end of the pull-up resistor and the ground, and the first switch transistor, the second switch transistor, the third switch transistor and the fourth switch transistor are all grounded, and the fault alert signal is a voltage value at the other end of the pull-up resistor;
the preset fault state signals comprise an over current protection signal, an over temperature protection signal, a short current protection signal and an over voltage protection signal, wherein the over current protection signal is configured to drive the first switch transistor to be turned on or off, the over temperature protection signal is configured to drive the second switch transistor to be turned on or off, the short current protection signal is configured to drive the third switch transistor to be turned on or off, and the over voltage protection signal is configured to drive the fourth switch transistor to be turned on or off; and, at most one of the first switch transistor, the second switch transistor, the third switch transistor and the fourth switch transistor is turned on at the same moment.

In some embodiments, the conversion circuit comprises: a first switch transistor, a second switch transistor, a third switch transistor, a fourth switch transistor, a first resistor, a second resistor, a third resistor, a fourth resistor, a fifth resistor, a sixth resistor, a seventh resistor and a pull-up resistor; resistance values of the first resistor, the second resistor, the third resistor, the fourth resistor, the fifth resistor, the sixth resistor, the seventh resistor and the pull-up resistor are all the same;
the first switch transistor and the first resistor are connected in series to form a first branch circuit, the second switch transistor and the second resistor are connected in series to form a second branch circuit, the third switch transistor and the third resistor are connected in series to form a third branch circuit, and the fourth switch transistor and the fourth resistor are connected in series to form a fourth branch circuit; one end of the pull-up resistor is connected to a power source, the first branch circuit, the second branch circuit, the third branch circuit and the fourth branch circuit are connected in parallel between the other end of the pull-up resistor and the ground, and the first switch transistor, the second switch transistor, the third switch transistor and the fourth switch transistor are all grounded, the fifth resistor is connected in series between the first resistor and the second resistor, the sixth resistor is connected in series between the second resistor and the third resistor, the seventh resistor is connected in series between the third resistor and the fourth resistor, and the fault alert signal is a voltage value at the other end of the pull-up resistor;
the preset fault state signals comprise an over current protection signal, an over temperature protection signal, a short current protection signal and an over voltage protection signal, the over current protection signal is configured to drive the first switch transistor to be turned on or off, the over temperature protection signal is configured to drive the second switch transistor to be turned on or off, the short current protection signal is configured to drive the third switch transistor to be turned on or off, and the over voltage protection signal is configured to drive the fourth switch transistor to be turned on or off; and at most one of the first switch transistor, the second switch transistor, the third switch transistor and the fourth switch transistor is turned on at the same moment.

In some embodiments, the fault alert signal outputted by each conversion circuit is analyzed by a controller, to determine a faulty hot swap controller chip and the fault type of the hot swap controller chip, comprises:
in response to the fault alert signal outputted by a conversion circuit and being equal to half of a power source voltage, it is confirmed that a hot swap controller chip corresponding to the conversion circuit outputting the fault alert signal being equal to half of the power source voltage has a fault, and the fault type is over current protection of the hot swap controller chip;
in response to the fault alert signal outputted by a conversion circuit being equal to two thirds of the power source voltage, it is confirmed that a hot swap controller chip corresponding to the conversion circuit outputting the fault alert signal being equal to two thirds of the power source voltage has a fault, and the fault type is over temperature protection of the hot swap controller chip; in response to the fault alert signal outputted by a conversion circuit being equal to three quarters of the power source voltage, it is confirmed confirm that a hot swap controller chip corresponding to the conversion circuit outputting the fault alert signal being equal to three quarters of the power source voltage has a fault, and the fault type is short current protection of the hot swap controller chip;
in response to the fault alert signal outputted by a conversion circuit being equal to four fifths of the power source voltage, it is confirmed that a hot swap controller chip corresponding to the conversion circuit outputting the fault alert signal being equal to four fifths of the power source voltage has a fault, and the fault type is over voltage protection of the hot swap controller chip; and
in response to the fault alert signal outputted by a conversion circuit being equal to zero, it is confirmed that a hot swap controller chip corresponding to the conversion circuit outputting the fault alert signal being equal to zero has no fault.

In some embodiments, each of the hot swap controller chips further has a current detection signal, and the controller is further configured to collect the current detection signal of each of the hot swap controller chips, process the collected current detection signal, and then generate a current balance alert signal and a current balance control signal according to a preset decision rule; and the method further comprises:
a first input end of an AND gate is connected to a power-on signal, a second input end of the AND gate is connected to the current balance control signal, and an output end of the AND gate is connected to an enable signal pin of each of the hot swap controller chips.

In some embodiments, the collected current detection signal is processed, and then the current balance alert signal and the current balance control signal are generated according to the preset decision rule, comprise:
an average value of all collected current detection signals is calculated;
in response to the current detection signal of any one of the hot swap controller chips being less than 0.6 times the average value or greater than 1.6 times the average value, the current balance alert signal indicating that an alert is required is outputted, and the current balance control signal for turning off the hot swap controller chips is outputted;
in response to the current detection signal of each of the hot swap controller chips being greater than or equal to 0.6 times the average value and less than or equal to 1.6 times the average value, and the current detection signal of any one of the hot swap controller chips being greater than or equal to 0.6 times the average value and less than 0.9 times the average value, the current balance alert signal indicating that an alert is required is outputted, and a current balance control signal for not turning off the hot swap controller chips is outputted;
in response to the current detection signal of each of the hot swap controller chips being greater than or equal to 0.6 times the average value and less than or equal to 1.6 times the average value, and the current detection signal of any one of the hot swap controller chip being greater than 1.1 times the average value and less than or equal to 1.6 times the average value, the current balance alert signal indicating that an alert is required is outputted, and the current balance control signal for not turning off the hot swap controller chips is outputted; and
in response to the current detection signals of each of the hot swap controller chips being greater than or equal to 0.9 times the average value and less than or equal to 1.1 times the average value, the current balance alert signal indicating that an alert is not required is outputted, and the current balance control signal for not turning off the hot swap controller chips is outputted.

In some embodiments, the average value of all collected current detection signals is calculated, comprises:
the average value of all current detection signals is calculated by the following formula:

$${I}_{a v g} = \frac{1}{n} {\sum }_{i = 0}^{n} IMONi ;$$

IMONi is a current detection signal of an ith hot swap controller chip, and I_{avg} is an average value of all current detection signals.

In some embodiments, the controller is a baseboard management controller.

According to a third aspect of some embodiments of the present disclosure, further provided is a computer device, the computer device comprising:
at least one processor; and
a memory, wherein the memory stores a computer program that can run on the processor, and when the processor executes the program, the described parallel hot swap controller chip fault processing method is executed.

According to a fourth aspect of some embodiments of the present disclosure, further provided is a computer non-transitory readable storage medium, wherein the computer non-transitory readable storage medium stores a computer program, and when the computer program is executed by a processor, implement the following operations:
connecting a plurality of hot swap controller chips in parallel, each of the hot swap controller chips having a plurality of preset fault state signals;
converting, by each of conversion circuits, the preset fault state signals into a fault alert signal, wherein the conversion circuits correspond to the hot swap controller chips on a one-to-one basis; and
analyzing, by a controller, the fault alert signal outputted by each of the conversion circuit, to determine a faulty hot swap controller chip and a fault type of the faulty hot swap controller chip.

In the described parallel hot swap controller chip fault processing apparatus, the preset fault state signals inside each hot swap controller chip are converted into a fault alert signal by the conversion circuit, and then the controller analyses and judges the fault alert signal so as to locate specific fault location and fault reason, and thus automatic fault location and fault diagnosis are realized, thereby avoiding the investment of manpower and material resources caused by field analysis by research and development personnel, and increasing the fault location efficiency.

In addition, some embodiments of the present disclosure further provide a parallel hot swap controller chip fault processing method, a computer device and a computer non-transitory readable storage medium, which can also achieve the described technical effects, and will not be described herein again.

### BRIEF DESCRIPTION OF THE DRAWINGS

In order to describe the technical solutions in embodiments of the present disclosure or in the related art more clearly, hereinafter, accompanying drawings requiring to be used in the embodiments or the related art will be introduced briefly. Apparently, the accompanying drawings in the following description merely relate to some embodiments of the present disclosure, and for a person of ordinary skill in the art, other embodiments can also be derived from these accompanying drawings without involving any inventive effort.

FIG. 1 is a schematic structural diagram of a conventional application scenario in which a plurality of HSCs are connected in parallel;

FIG. 2 is a schematic diagram of a parallel HSC chip fault processing apparatus provided according to some embodiments of the present disclosure;

FIG. 3A is a schematic structural diagram of a conversion circuit provided according to some embodiments of the present disclosure;

FIG. 3B is a schematic structural diagram of a conversion circuit provided according to some other embodiments of the present disclosure;

FIG. 4 is a schematic diagram of a parallel HSC current balance detection and judgment principle provided according to some other embodiments of the present disclosure;

FIG. 5 is a schematic diagram of a parallel HSC chip fault processing method provided according to some embodiments of the present disclosure; and

FIG. 6 is an internal structural diagram of a computer device according to some other embodiments of the present disclosure.

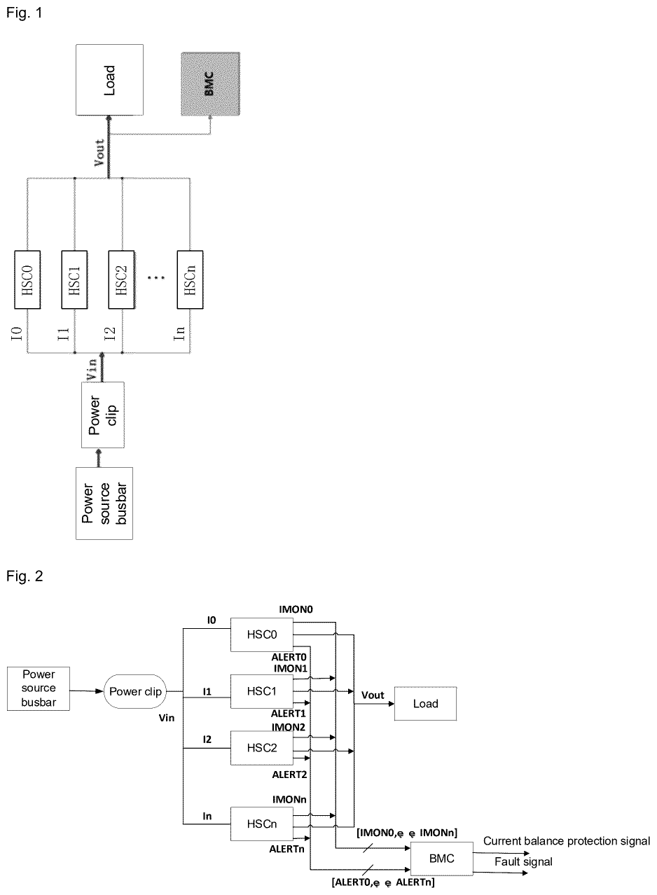

### DETAILED DESCRIPTION OF THE EMBODIMENTS

In order to make objects, technical solutions and advantages of some embodiments of the present disclosure clearly understood, hereinafter, embodiments of the present disclosure will be further described in detail in conjunction with specific embodiments and with reference to the accompanying drawings.

It should be noted that in the embodiments of the present disclosure, all expressions using “first” and “second” are used to distinguish two different entities having the same name or distinguish different parameters. Hence, “first” and “second” are only used for convenience of expression, should not be understood as limitations to embodiments of the present disclosure, and this will not be described one by one in subsequent embodiments.

In some embodiments, refer to FIG. 2, some embodiments of the present disclosure provide an apparatus of processing a fault of a parallel hot swap controller chip, comprising:
a plurality of parallel hot swap controller chips, each of the hot swap controller chips having a plurality of preset fault state signals;
a plurality of conversion circuits, the conversion circuits corresponding to the hot swap controller chips on a one-to-one basis, and each of the conversion circuit being configured to convert the plurality of preset fault state signals into a fault alert signal and outputting the fault alert signal; and
a controller, configured to analyze the fault alert signal outputted by each of the conversion circuits to determine a faulty hot swap controller chip and a fault type of the faulty hot swap controller chip.

In the described parallel hot swap controller chip fault processing apparatus, the preset fault state signals inside each hot swap controller chip are converted into a fault alert signal by the conversion circuit, and then the controller analyses and judges the fault alert signal so as to locate specific fault location and fault reason, and thus automatic fault location and fault diagnosis are realized, thereby avoiding the investment of manpower and material resources caused by field analysis by research and development personnel, and increasing the fault location efficiency.

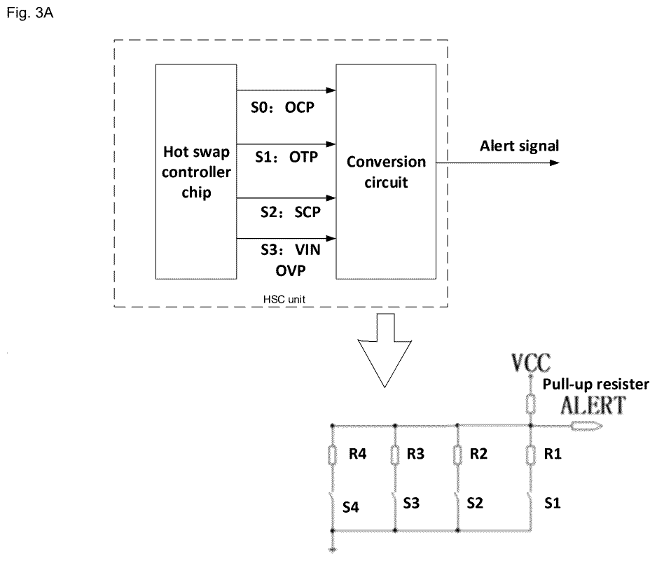

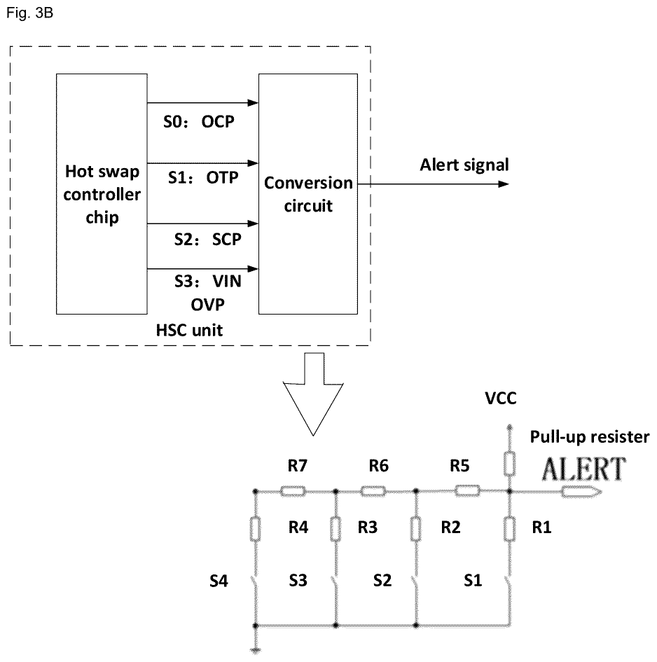

In some embodiments, please refer to FIG. 3A, the conversion circuit comprises: a first switch transistor S1, a second switch transistor S2, a third switch transistor S3, a fourth switch transistor S4, a first resistor R1, a second resistor R2, a third resistor R3, a fourth resistor R4 and a pull-up resistor; wherein resistance values of the first resistor R1, the second resistor R2, the third resistor R3 and the fourth resistor R4 are all different;
the first switch transistor S1 and the first resistor R1 are connected in series to form a first branch circuit, the second switch transistor S2 and the second resistor R2 are connected in series to form a second branch circuit, the third switch transistor S3 and the third resistor R3 are connected in series to form a third branch circuit, and the fourth switch transistor S4 and the fourth resistor R4 are connected in series to form a fourth branch circuit; one end of the pull-up resistor is connected to a power source, the first branch circuit, the second branch circuit, the third branch circuit and the fourth branch circuit are connected in parallel between the other end of the pull-up resistor and the ground, and the first switch transistor S1, the second switch transistor S2, the third switch transistor S3 and the fourth switch transistor S4 are all grounded, and the fault alert signal is a voltage value at the other end of the pull-up resistor;
the preset fault state signals comprise an over current protection signal, an over temperature protection signal, a short current protection signal and an over voltage protection signal, wherein the over current protection signal is configured to drive the first switch transistor S1 to be turned on or off, the over temperature protection signal is configured to drive the second switch transistor S2 to be turned on or off, the short current protection signal is configured to drive the third switch transistor S3 to be turned on or off, and the over voltage protection signal is configured to drive the fourth switch transistor S4 to be turned on or off; and, at most one of the first switch transistor S1, the second switch transistor S2, the third switch transistor S3 and the fourth switch transistor S4 is turned on at the same moment.

In some embodiments, please refer to FIG. 3B, the conversion circuit comprises: a first switch transistor S1, a second switch transistor S2, a third switch transistor S3, a fourth switch transistor S4, a first resistor R1, a second resistor R2, a third resistor R3, a fourth resistor R4, a fifth resistor R5, a sixth resistor R6, a seventh resistor R7 and a pull-up resistor; resistance values of the first resistor R1, the second resistor R2, the third resistor R3, the fourth resistor R4, the fifth resistor R5, the sixth resistor R6, the seventh resistor R7 and the pull-up resistor are all the same;
the first switch transistor S1 and the first resistor R1 are connected in series to form a first branch circuit, the second switch transistor S2 and the second resistor R2 are connected in series to form a second branch circuit, the third switch transistor S3 and the third resistor R3 are connected in series to form a third branch circuit, and the fourth switch transistor S4 and the fourth resistor R4 are connected in series to form a fourth branch circuit; one end of the pull-up resistor is connected to a power source, the first branch circuit, the second branch circuit, the third branch circuit and the fourth branch circuit are connected in parallel between the other end of the pull-up resistor and the ground, and the first switch transistor S1, the second switch transistor S2, the third switch transistor S3 and the fourth switch transistor S4 are all grounded, the fifth resistor R5 is connected in series between the first resistor R1 and the second resistor R2, the sixth resistor R6 is connected in series between the second resistor R2 and the third resistor R3, the seventh resistor R7 is connected in series between the third resistor R3 and the fourth resistor R4, and the fault alert signal is a voltage value at the other end of the pull-up resistor;
the preset fault state signals comprise an over current protection signal, an over temperature protection signal, a short current protection signal and an over voltage protection signal, the over current protection signal is configured to drive the first switch transistor S1 to be turned on or off, the over temperature protection signal is configured to drive the second switch transistor S2 to be turned on or off, the short current protection signal is configured to drive the third switch transistor S3 to be turned on or off, and the over voltage protection signal is configured to drive the fourth switch transistor S4 to be turned on or off; and, at most one of the first switch transistor S1, the second switch transistor S2, the third switch transistor S3 and the fourth switch transistor S4 is turned on at the same moment.

In some embodiments, the controller is further configured to:
in response to the fault alert signal outputted by a conversion circuit and being equal to half of a power source voltage, confirm that a hot swap controller chip corresponding to the conversion circuit outputting the fault alert signal being equal to half of the power source voltage has a fault, and the fault type is over current protection of the hot swap controller chip;
in response to the fault alert signal outputted by a conversion circuit and being equal to two thirds of the power source voltage, confirm that a hot swap controller chip corresponding to the conversion circuit outputting the fault alert signal being equal to two thirds of the power source voltage has a fault, and the fault type is over temperature protection of the hot swap controller chip;
in response to the fault alert signal outputted by a conversion circuit and being equal to three quarters of the power source voltage, confirm that a hot swap controller chip corresponding to the conversion circuit outputting the fault alert signal being equal to three quarters of the power source voltage has a fault, and the fault type is short current protection of the hot swap controller chip;
in response to the fault alert signal outputted by a conversion circuit and being equal to four fifths of the power source voltage, confirm that a hot swap controller chip corresponding to the conversion circuit outputting the fault alert signal being equal to four fifths of the power source voltage has a fault, and the fault type is over voltage protection of the hot swap controller chip; and
in response to the fault alert signal outputted by a conversion circuit and being equal to zero, confirm that a hot swap controller chip corresponding to the conversion circuit outputting the fault alert signal being equal to zero has no fault.

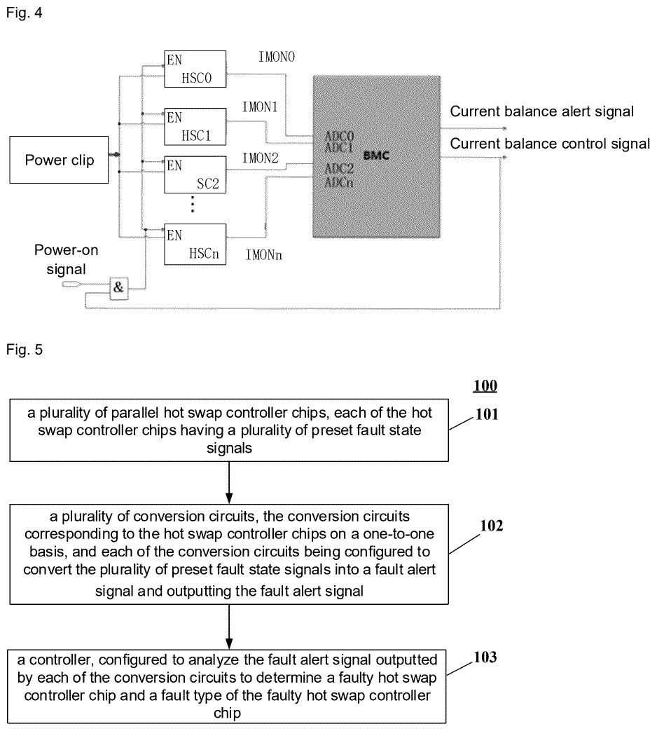

In some embodiments, please refer to FIG. 4, each of the hot swap controller chip further has a current detection signal, and the controller is further configured to collect the current detection signal of each of the hot swap controller chip, process the collected current detection signal, and then generate a current balance alert signal and a current balance control signal according to a preset decision rule; and
the apparatus further comprises an AND gate, a first input end of the AND gate is connected to a power-on signal, a second input end of the AND gate is connected to the current balance control signal, and an output end of the AND gate is connected to an enable signal pin of each of the hot swap controller chips.

In some embodiments, the controller is further configured to:
calculate an average value of all collected current detection signals;
in response to the current detection signal of any one of the hot swap controller chips being less than 0.6 times the average value or greater than 1.6 times the average value, output the current balance alert signal indicating that an alert is required, and output a current balance control signal for turning off the hot swap controller chips;
in response to the current detection signal of each of the hot swap controller chips being greater than or equal to 0.6 times the average value and less than or equal to 1.6 times the average value, and the current detection signal of any one of the hot swap controller chips being greater than or equal to 0.6 times the average value and less than 0.9 times the average value, output the current balance alert signal indicating that an alert is required, and output the current balance control signal for not turning off the hot swap controller chip;
in response to the current detection signal of each of the hot swap controller chips being greater than or equal to 0.6 times the average value and less than or equal to 1.6 times the average value, and the current detection signal of any one of the hot swap controller chip being greater than 1.1 times the average value and less than or equal to 1.6 times the average value, output the current balance alert signal indicating that an alert is required, and output the current balance control signal for not turning off the hot swap controller chips; and
in response to the current detection signals of each of the hot swap controller chips being greater than or equal to 0.9 times the average value and less than or equal to 1.1 times the average value, output the current balance alert signal indicating that an alert is not required, and output the current balance control signal for not turning off the hot swap controller chips.

In some embodiments, the controller is a baseboard management controller.

In still some other embodiments, in order to facilitate understanding of solutions of some embodiments of the present disclosure, hereinafter, a data center server being a load is taken as an example, and the load uses n (n is greater than or equal to 2) HSC (hot swap controller) chips to supply power in parallel. Refer to FIGS. 2 to 4 again, this embodiment provides another parallel HSC chip fault processing apparatus, which comprises: a POWER CLIP connector, HSC0, HSC1, . . . , HSCn, conversion circuits, a LOAD, and a BMC. This apparatus differs from that in a traditional method (a separate BMC monitors voltage signals transmitted by HSCs) in that: (1) OCP, SCP, OTP and OVP fault states inside the HSCs are made to correspond to a voltage value of an alert signal ALERT, and specific fault information is located by judgment of the voltage value of the alert signal inside the BMC. IMON signals of a plurality of HSC chips are introduced into the BMC, and after digital processing is performed on the IMON signals inside the BMC, a current balance alert signal and a current balance control signal are generated according to a decision rule. In addition, the current balance control signal is used to control whether an HSC is turned off, such that the problem of board burning caused by unbalanced current can be effectively avoided. Functions of each part of the apparatus are described in detail below:

a plurality of input ends of HSC0, HSC1, . . . , and HSCn are connected in parallel to acquire power Vin from the BUSBAR through the POWER CLIP connector, and output ends thereof are connected in parallel and are converged to output Vout to supply power to the LOAD.

The current flowing through each HSC chip is: 10, 11, . . . , In in sequence. The HSC chips respectively lead out signals: [IMON0, IMON1, . . . , IMONn] and [ALERT0, ALERT1 . . . , ALERTn], which are connected to ADC I/O (analog-to-digital converter input/output) ports of the BMC. [IMON0, IMON1, . . . , IMONn] represent current detection signals led out from HSC0, HSC1, . . . , HSCn chips, representing the magnitudes of currents flowing through each HSC chip.

[ALERT0, ALERT1, . . . , ALERTn] represent alert signals led out from the HSC0, HSC1, . . . , HSCn chips, and represent a specific fault triggered by each HSC chip.

The BMC performs judgment processing according to voltage values of the collected current signal and alert signal, provides a fault location result, and triggers a current balance protection signal, i.e. Current Balance.

As shown in FIG. 3B, this figure is a circuit structure for HSC fault location distinguishing and processing proposed in the present embodiment. Four common faults in an HSC chip are taken as an example (when S0, S1, S2 and S3 are at low levels, a conversion line switch is closed), wherein S0 represents: OCP (over current protection) is triggered; S1 represents: OTP (over temperature protection) is triggered; S2 represents: SCP (Short Circuit Protection) is triggered; and S3 represents: OVP (Over Voltage Protection) is triggered. S0, S1, S2 and S3 are logic level signals, the conversion line at the lower right of FIG. 3B is controlled by using the four logic level signals, and ALERT signals of different voltage values are outputted, and the conversion relationships thereof are shown in Table 1.

TABLE 1
Correlation between fault alert signal voltage values and fault types

| | | | | | ALERT | |
|---|---|---|---|---|---|---|
| | | | | | signal | |
| Fault | | | | | voltage | Illustration of corresponding fault |
| state | Logic level | | | | value | location |
| S0 | 0 | 1 | 1 | 1 | VCC/2 | When the BMC detects that an |
| | | | | | | ALERT voltage value is 0.5VCC, |
| | | | | | | it is determined that OCP occurs |
| S1 | 1 | 0 | 1 | 1 | 2VCC/3 | When the BMC detects that an |
| | | | | | | ALERT voltage value is 0.67VCC, |
| | | | | | | it is determined that OTP occurs |
| S2 | 1 | 1 | 0 | 1 | 3VCC/4 | When the BMC detects that an |
| | | | | | | ALERT voltage value is 0.75VCC, |
| | | | | | | it is determined that SCP occurs |
| S3 | 1 | 1 | 1 | 0 | 4VCC/5 | When the BMC detects that an |
| | | | | | | ALERT voltage value is 0.8VCC, |
| | | | | | | it is determined that OVP occurs |

FIG. 4 shows a current balance diagnosis structure for detecting a circuit in which a plurality of HSCs are connected in parallel. Current detection signals: [IMON0, IMON1, . . . , IMONn] generated by HSC0, HSC1, . . . , HSCn are transmitted to ADC I/O ports: [ADC0, ADC1, . . . , ADCn] of the BMC. After digital processing is performed on the current detection signals by the interior of the BMC chip, a current average value is calculated according to the following formula:

$${I}_{a v g} = \frac{1}{n} {\sum }_{i = 0}^{n} IMONi$$

IMONI and I_{avg} have the following judgment relationships as shown in Table 2:

TABLE 2
Correlation between IMONi, current balance alert
signals, and current balance control signals

| | Current | Current | |
|---|---|---|---|
| | Balance | Balance | |
| IMONI | ALERT | SHUT | Corresponding actions |
| IMONi < 0.6*I_{avg} | 0 | 0 | The BMC gives an alert, and |
| | | | shuts off the HSC |
| 0.6*l_{avg}g ≤ IMONi < | 0 | 1 | The BMC gives an alert, and |
| 0.9*l_{avg} | | | the HSC is still working |
| 0.9*I_{avg} ≤ IMONi ≤ | 1 | 1 | The BMC has no alert, and |
| 1.1*l_{avg} | | | the HSC works normally |
| 1.1*I_{avg} < IMONi ≤ | 0 | 1 | The BMC gives an alert, and |
| 1.6*l_{avg} | | | the HSC is still working |
| IMONi > 1.6*l_{avg} | 0 | 0 | The BMC gives an alert, and |
| | | | shuts off the HSC |

The BMC will perform comparison and judgment according to IMONi, and generate a Current Balance ALERT signal and a Current Balance SHUT current balance control signal. The correlation thereof and the generated corresponding actions are as shown in Table 2 above. When the Balance SHUT current balance control signal is at a low level (In embodiments of present disclosure, the low level can represent 0 (namely, a logic 0), which indicates a preset voltage, such as a voltage being equal to or greater than Ov and being equal to or less than 0.2 v), the HSC is shut off after the current balance control signal and a power-on signal PSON pass through the “AND gate”. Thus, the HSC is prevented from being burnt out due to severe unbalanced current.

A working process of the described parallel HSC chip fault processing apparatus will be described in detail below:

Operation I, on the basis of a total power consumption P_T of a server system having configurations which comprise a CPU, a memory, a hard disk array, a system fan module and a node main board, a maximum current value I_T of a power supply path from the BUSBAR to the HSC is determined.

Step II, according to the maximum current value I_T, a POWER CLIP connector satisfying the magnitude of current passing, an appropriate model of HSC chip (such as MP5991GLU-Z) and the number of HSC chips requiring to be connected in parallel are selected.

Operation III, input ends and output ends of each group of HSC chips are connected in parallel. IMON (current detection signal) pins of each group of HSC chips are connected with ADC I/O (analog-to-digital conversion input/output) pins of the BMC (baseboard management controller). ALERT (alert signal) pins of the HSC chips are connected with ADC I/O (analog-to-digital conversion input/output) pins of the BMC (baseboard management controller).

Operation IV, a decision rule of alert signal fault information, and current balance signal alert and control decision rules are introduced into BMC firmware.

Operation V, a current balance control signal Current Balance SHUT and a node power-on signal PSON which are generated by the BMC pass through a logic “AND” gate chip, and generated output signals are connected in parallel with EN pins of a plurality of HSC chips.

The parallel HSC chip fault processing at least has the following beneficial technical effects: First, OCP, SCP, OTP and OVP fault states inside the HSCs are made to correspond to a voltage value of an alert signal ALERT, and specific fault information is located by judgment of the voltage value of the alert signal inside the BMC, thereby avoiding the investment of manpower and material resources caused by field analysis by research and development personnel, and increasing the fault location efficiency. Secondly, IMON signals of a plurality of HSC chips are introduced into the BMC, and after digital processing is performed on the IMON signals inside the BMC, a current balance alert signal and a current balance control signal are generated according to a decision rule. In addition, the current balance control signal is used to control whether an HSC is turned off. The problem of board burning caused by unbalanced current can be effectively avoided, and the safety of supplying power for servers can be enhanced.

In still some other embodiments, refer to FIG. 5, some embodiments of the present disclosure further provide a parallel hot swap controller chip fault processing method 100, said method comprising:

Operation 101, a plurality of hot swap controller chips are connected in parallel, wherein each hot swap controller chip has several preset fault state signals;

Operation 102, by each of using a conversion circuits, the several preset fault state signals are converted into a fault alert signal, wherein the conversion circuits correspond to the hot swap controller chips on a one-to-one basis; and

Operation 103, the fault alert signal outputted by each conversion circuit is analyzed by a controller, so as to determine a faulty hot swap controller chip and the fault type of the hot swap controller chip.

In the parallel HSC chip fault processing method, the preset fault state signals inside each HSC chip are converted into a fault alert signal by the conversion circuit, and then the controller analyses and judges the fault alert signal so as to locate specific fault location and fault reason, and thus automatic fault location and fault diagnosis are realized, thereby avoiding the investment of manpower and material resources caused by field analysis by research and development personnel, and increasing the fault location efficiency.

In some embodiments, the conversion circuit comprises: a first switch transistor S1, a second switch transistor S2, a third switch transistor S3, a fourth switch transistor S4, a first resistor R1, a second resistor R2, a third resistor R3, a fourth resistor R4 and a pull-up resistor; wherein resistance values of the first resistor R1, the second resistor R2, the third resistor R3 and the fourth resistor R4 are all different;
the first switch transistor S1 and the first resistor R1 are connected in series to form a first branch circuit, the second switch transistor S2 and the second resistor R2 are connected in series to form a second branch circuit, the third switch transistor S3 and the third resistor R3 are connected in series to form a third branch circuit, and the fourth switch transistor S4 and the fourth resistor R4 are connected in series to form a fourth branch circuit; one end of the pull-up resistor is connected to a power source, the first branch circuit, the second branch circuit, the third branch circuit and the fourth branch circuit are connected in parallel between the other end of the pull-up resistor and the ground, and the first switch transistor S1, the second switch transistor S2, the third switch transistor S3 and the fourth switch transistor S4 are all grounded, and the fault alert signal is a voltage value at the other end of the pull-up resistor;
the preset fault state signals comprise an over current protection signal, an over temperature protection signal, a short current protection signal and an over voltage protection signal, wherein the over current protection signal is configured to drive the first switch transistor S1 to be turned on or off, the over temperature protection signal is configured to drive the second switch transistor S2 to be turned on or off, the short current protection signal is configured to drive the third switch transistor S3 to be turned on or off, and the over voltage protection signal is configured to drive the fourth switch transistor S4 to be turned on or off; and, at most one of the first switch transistor S1, the second switch transistor S2, the third switch transistor S3 and the fourth switch transistor S4 is turned on at the same moment.

In some embodiments, the conversion circuit comprises: a first switch transistor S1, a second switch transistor S2, a third switch transistor S3, a fourth switch transistor S4, a first resistor R1, a second resistor R2, a third resistor R3, a fourth resistor R4, a fifth resistor R5, a sixth resistor R6, a seventh resistor R7 and a pull-up resistor; wherein resistance values of the first resistor R1, the second resistor R2, the third resistor R3, the fourth resistor R4, the fifth resistor R5, the sixth resistor R6, the seventh resistor R7 and the pull-up resistor are all the same;
the first switch transistor S1 and the first resistor R1 are connected in series to form a first branch circuit, the second switch transistor S2 and the second resistor R2 are connected in series to form a second branch circuit, the third switch transistor S3 and the third resistor R3 are connected in series to form a third branch circuit, and the fourth switch transistor S4 and the fourth resistor R4 are connected in series to form a fourth branch circuit; one end of the pull-up resistor is connected to a power source, the first branch circuit, the second branch circuit, the third branch circuit and the fourth branch circuit are connected in parallel between the other end of the pull-up resistor and the ground, the first switch transistor S1, the second switch transistor S2, the third switch transistor S3 and the fourth switch transistor S4 are all grounded, the fifth resistor R5 is connected in series between the first resistor R1 and the second resistor R2, the sixth resistor R6 is connected in series between the second resistor R2 and the third resistor R3, the seventh resistor R7 is connected in series between the third resistor R3 and the fourth resistor R4, and the fault alert signal is a voltage value at the other end of the pull-up resistor;
the preset fault state signals comprise an over current protection signal, an over temperature protection signal, a short current protection signal and an over voltage protection signal, the over current protection signal is configured to drive the first switch transistor S1 to be turned on or off, the over temperature protection signal is configured to drive the second switch transistor S2 to be turned on or off, the short current protection signal is configured to drive the third switch transistor S3 to be turned on or off, and the over voltage protection signal is configured to drive the fourth switch transistor S4 to be turned on or off; and at most one of the first switch transistor S1, the second switch transistor S2, the third switch transistor S3 and the fourth switch transistor S4 is turned on at the same moment.

In some embodiments, step 103 that the fault alert signal outputted by each conversion circuit is analyzed by a controller, to determine a faulty hot swap controller chip and the fault type of the hot swap controller chip, comprises:
in response to the fault alert signal outputted by a conversion circuit and being equal to one half of a power source voltage, it is confirmed that a hot swap controller chip corresponding to the conversion circuit outputting the fault alert signal being equal to half of the power source voltage has a fault, and the fault type is over current protection of the hot swap controller chip;
in response to the fault alert signal outputted by a conversion circuit and being equal to two thirds of the power source voltage, it is confirmed that a hot swap controller chip corresponding to the conversion circuit outputting the fault alert signal being equal to two thirds of the power source voltage has a fault, and the fault type is over temperature protection of the hot swap controller chip;
in response to the fault alert signal outputted by a conversion circuit and being equal to three quarters of the power source voltage, it is confirmed confirm that a hot swap controller chip corresponding to the conversion circuit outputting the fault alert signal being equal to three quarters of the power source voltage has a fault, and the fault type is short current protection of the hot swap controller chip;
in response to the fault alert signal outputted by a conversion circuit and being equal to four fifths of the power source voltage, it is confirmed that a hot swap controller chip corresponding to the conversion circuit outputting the fault alert signal being equal to four fifths of the power source voltage has a fault, and the fault type is over voltage protection of the hot swap controller chip; and
in response to the fault alert signal outputted by a conversion circuit being equal to zero, it is confirmed that a hot swap controller chip corresponding to the conversion circuit outputting the fault alert signal being equal to zero has no fault.

In some embodiments, each of the hot swap controller chips further has a current detection signal, and the controller is further configured to collect the current detection signal of each of the hot swap controller chips, process the collected current detection signal, and then generate a current balance alert signal and a current balance control signal according to a preset decision rule; and the method further comprises:

a first input end of an AND gate is connected to a power-on signal, a second input end of the AND gate is connected to the current balance control signal, and an output end of the AND gate is connected to an enable signal pin of each hot swap controller chip.

In some embodiments, the collected current detection signal is processed, and then the current balance alert signal and the current balance control signal are generated according to the preset decision rule, comprise:
an average value of all collected current detection signals is calculated;
in response to the current detection signal of any one of the hot swap controller chips being less than 0.6 times the average value or greater than 1.6 times the average value, the current balance alert signal indicating that an alert is required is outputted, and the current balance control signal for turning off the hot swap controller chip is outputted;
in response to the current detection signal of all the hot swap controller chips being greater than or equal to 0.6 times the average value and less than or equal to 1.6 times the average value, and the current detection signal of any one hot swap controller chip being greater than or equal to 0.6 times the average value and less than 0.9 times the average value, a current balance alert signal indicating that an alert is required is outputted, and a current balance control signal for not turning off the hot swap controller chip is outputted;
in response to the current detection signal of all the hot swap controller chips being greater than or equal to 0.6 times the average value and less than or equal to 1.6 times the average value, and the current detection signal of any one hot swap controller chip being greater than 1.1 times the average value and less than or equal to 1.6 times the average value, a current balance alert signal indicating that an alert is required is outputted, and a current balance control signal for not turning off the hot swap controller chip is outputted; and
in response to the current detection signal of all the hot swap controller chips being greater than or equal to 0.9 times the average value and less than or equal to 1.1 times the average value, a current balance alert signal indicating that an alert is not required is outputted, and a current balance control signal for not turning off the hot swap controller chip is outputted.

In some embodiments, the controller is a baseboard management controller.

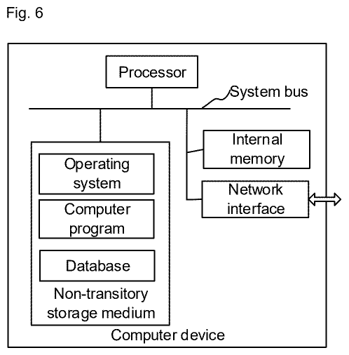

According to another aspect of some embodiments of the present disclosure, provided is a computer device, wherein the computer device may be a server, and for an internal structural diagram thereof, reference is made to FIG. 6. The computer device comprises a processor, a memory, a network interface and a database which are connected by a system bus. The processor of the computer device is used to provide computing and control capabilities. The memory of the computer device comprises a non-transitory readable storage medium and an internal memory. The non-transitory readable storage medium stores an operating system, a computer program and a database. The internal memory provides an environment for operation of the operating system and the computer program in the non-transitory readable storage medium. The database of the computer device is used to store data. The network interface of the computer device is used to communicate with an external terminal via network connection. The computer program, when executed by the processor, implements the described An method of processing a fault of a parallel hot swap controller chip, said method comprises the following steps:
a plurality of hot swap controller chips are connected in parallel, each of the hot swap controller chips having a plurality of preset fault state signals;
by using a conversion circuit corresponding to each of the hot swap controller chips, the preset fault state signals are converted into a fault alert signal and the fault alert signal is outputted the fault alert signal; and
the fault alert signal outputted by each of the conversion circuit is analyzed by a controller, to determine a faulty hot swap controller chip and a fault type of the faulty hot swap controller chip.

According to still another aspect of some embodiments of the present disclosure, provided is a computer non-transitory readable storage medium, which stores a computer program, which when executed by a processor, implements the described An method of processing a fault of a parallel hot swap controller chip, comprising executing the following steps:
a plurality of hot swap controller chips are connected in parallel, each of the hot swap controller chip has having a plurality of preset fault state signals;
by using a conversion circuit corresponding to each of the hot swap controller chips, the preset fault state signals are converted into a fault alert signal and the fault alert signal is outputted the fault alert signal; and
the fault alert signal outputted by each of the conversion circuit is analyzed by a controller, to determine faulty hot swap controller chip and the fault type of the faulty hot swap controller chip.

A person of ordinary skill in the art would understand that all or some processes of the methods in the described embodiments may be completed by a computer program instructing related hardware. The computer program can be stored in a non-transitory computer-readable storage medium, and when the computer program is executed, the processes in the described various method embodiments can be included. Any references to memory, storage, database, or other media used in the embodiments provided in the present disclosure may comprise a non-transitory memory and/or a transitory memory. The non-transitory memory may comprise a read-only memory (ROM), a programmable ROM (PROM), an electrically programmable ROM (EPROM), an electrically erasable programmable ROM (EEPROM), or flash memory. The transitory memory may comprise a random access memory (RAM) or an external cache memory. By way of illustration rather than limitation, the RAM may be available in a variety of forms, such as static RAM (SRAM), dynamic RAM (DRAM), synchronous DRAM (SDRAM), double data rate SDRAM (DDRSDRAM), enhanced SDRAM (ESDRAM), synchronous link (Synchlink) DRAM (SLDRAM), memory bus (Rambus) direct RAM (RDRAM), direct memory bus dynamic RAM (DRDRAM), and memory bus dynamic RAM (RDRAM), etc.

Various technical features of the embodiments above can be combined in any way, and in order to make the illustration brief, all possible combinations of the technical features of the embodiments above are not described. However, as long as the combinations of these technical features are not contradictory, the technical features should be considered to fall within the scope disclosed in the description.

The embodiments above merely represent several embodiments of the present disclosure, and the illustration thereof is specific and detailed, but the specific and detailed illustration cannot be understood as limiting the patent scope of the present disclosure. It should be noted that for a person of ordinary skill in the art, several modifications and improvements can be made without departing from the concept of the present disclosure, and all these modifications and improvements fall within the scope of protection of the present disclosure. Therefore, the patent scope of protection of the present disclosure shall be subject to the appended claims.

1. An apparatus of processing a fault of a parallel hot swap controller chip, comprising:
a plurality of parallel hot swap controller chips, each of the hot swap controller chips having a plurality of preset fault state signals;
a plurality of conversion circuits, the conversion circuits corresponding to the hot swap controller chips on a one-to-one basis, and each of the conversion circuits being configured to convert the plurality of preset fault state signals into a fault alert signal and outputting the fault alert signal; and
a controller, configured to analyze the fault alert signal outputted by each of the conversion circuits to determine a faulty hot swap controller chip and a fault type of the faulty hot swap controller chip.

2. The apparatus according to claim 1, wherein the number of the parallel hot swap controller chips is determined according to a maximum current value, and a model of each of the hot swap controller chips is determined according to the maximum current value; the maximum current value is a current value, 80% of which is equal to a current value corresponding to a total power consumption of a server system.

3. The apparatus according to claim 1, wherein the conversion circuit comprises: a first switch transistor, a second switch transistor, a third switch transistor, a fourth switch transistor, a first resistor, a second resistor, a third resistor, a fourth resistor and a pull-up resistor; resistance values of the first resistor, the second resistor, the third resistor and the fourth resistor are all different;
the first switch transistor and the first resistor are connected in series to form a first branch circuit, the second switch transistor and the second resistor are connected in series to form a second branch circuit, the third switch transistor and the third resistor are connected in series to form a third branch circuit, and the fourth switch transistor and the fourth resistor are connected in series to form a fourth branch circuit; one end of the pull-up resistor is connected to a power source, the first branch circuit, the second branch circuit, the third branch circuit and the fourth branch circuit are connected in parallel between the other end of the pull-up resistor and the ground, and the first switch transistor, the second switch transistor, the third switch transistor and the fourth switch transistor are all grounded, and the fault alert signal is a voltage value at the other end of the pull-up resistor;
the preset fault state signals comprise an over current protection signal, an over temperature protection signal, a short current protection signal and an over voltage protection signal, wherein the over current protection signal is configured to drive the first switch transistor to be turned on or off, the over temperature protection signal is configured to drive the second switch transistor to be turned on or off, the short current protection signal is configured to drive the third switch transistor to be turned on or off, and the over voltage protection signal is configured to drive the fourth switch transistor to be turned on or off; and at most one of the first switch transistor, the second switch transistor, the third switch transistor and the fourth switch transistor is turned on at the same moment.

4. The apparatus according to claim 1, wherein the conversion circuit comprises: a first switch transistor, a second switch transistor, a third switch transistor, a fourth switch transistor, a first resistor, a second resistor, a third resistor, a fourth resistor, a fifth resistor, a sixth resistor, a seventh resistor and a pull-up resistor; resistance values of the first resistor, the second resistor, the third resistor, the fourth resistor, the fifth resistor, the sixth resistor, the seventh resistor and the pull-up resistor are all the same;
the first switch transistor and the first resistor are connected in series to form a first branch circuit, the second switch transistor and the second resistor are connected in series to form a second branch circuit, the third switch transistor and the third resistor are connected in series to form a third branch circuit, and the fourth switch transistor and the fourth resistor are connected in series to form a fourth branch circuit; one end of the pull-up resistor is connected to a power source, the first branch circuit, the second branch circuit, the third branch circuit and the fourth branch circuit are connected in parallel between the other end of the pull-up resistor and the ground, and the first switch transistor, the second switch transistor, the third switch transistor and the fourth switch transistor are all grounded, the fifth resistor is connected in series between the first resistor and the second resistor, the sixth resistor is connected in series between the second resistor and the third resistor, the seventh resistor is connected in series between the third resistor and the fourth resistor, and the fault alert signal is a voltage value at the other end of the pull-up resistor;
the preset fault state signals comprise an over current protection signal, an over temperature protection signal, a short current protection signal and an over voltage protection signal, the over current protection signal is configured to drive the first switch transistor to be turned on or off, the over temperature protection signal is configured to drive the second switch transistor to be turned on or off, the short current protection signal is configured to drive the third switch transistor to be turned on or off, and the over voltage protection signal is configured to drive the fourth switch transistor to be turned on or off; and at most one of the first switch transistor, the second switch transistor, the third switch transistor and the fourth switch transistor is turned on at the same moment.

5. The apparatus according to claim 4, wherein the controller is further configured to:
in response to the fault alert signal outputted by a conversion circuit and being equal to half of a power source voltage, confirm that a hot swap controller chip corresponding to the conversion circuit outputting the fault alert signal being equal to half of the power source voltage has a fault, and the fault type is over current protection of the hot swap controller chip;
in response to the fault alert signal outputted by a conversion circuit and being equal to two thirds of the power source voltage, confirm that a hot swap controller chip corresponding to the conversion circuit outputting the fault alert signal being equal to two thirds of the power source voltage has a fault, and the fault type is over temperature protection of the hot swap controller chip;
in response to the fault alert signal outputted by a conversion circuit and being equal to three quarters of the power source voltage, confirm that a hot swap controller chip corresponding to the conversion circuit outputting the fault alert signal being equal to three quarters of the power source voltage has a fault, and the fault type is short current protection of the hot swap controller chip;
in response to the fault alert signal outputted by a conversion circuit and being equal to four fifths of the power source voltage, confirm that a hot swap controller chip corresponding to the conversion circuit outputting the fault alert signal being equal to four fifths of the power source voltage has a fault, and the fault type is over voltage protection of the hot swap controller chip; and
in response to the fault alert signal outputted by a conversion circuit and being equal to zero, confirm that a hot swap controller chip corresponding to the conversion circuit outputting the fault alert signal being equal to zero has no fault.

6. The apparatus according to claim 1, wherein each of the hot swap controller chips further has a current detection signal, and the controller is further configured to collect the current detection signal of each of the hot swap controller chips, process the collected current detection signal, and then generate a current balance alert signal and a current balance control signal according to a preset decision rule; and
the apparatus further comprises an AND gate, a first input end of the AND gate is connected to a power-on signal, a second input end of the AND gate is connected to the current balance control signal, and an output end of the AND gate is connected to an enable signal pin of each of the hot swap controller chips.

7. The apparatus according to claim 6, wherein the AND gate is configured to turn off, in a case where the received current balance control signal is at a low level, a hot swap controller chip corresponding to the current balance control signal.

8. The apparatus according to claim 6, wherein the controller is further configured to:
calculate an average value of all collected current detection signals;
in response to the current detection signal of any one of the hot swap controller chips being less than 0.6 times the average value or greater than 1.6 times the average value, output the current balance alert signal indicating that an alert is required, and output the current balance control signal for turning off the hot swap controller chips;
in response to the current detection signal of each of the hot swap controller chips being greater than or equal to 0.6 times the average value and less than or equal to 1.6 times the average value, and the current detection signal of any one of the hot swap controller chips being greater than or equal to 0.6 times the average value and less than 0.9 times the average value, output the current balance alert signal indicating that an alert is required, and output the current balance control signal for not turning off the hot swap controller chips;
in response to the current detection signal of each of the hot swap controller chips being greater than or equal to 0.6 times the average value and less than or equal to 1.6 times the average value, and the current detection signal of any one of the hot swap controller chips being greater than 1.1 times the average value and less than or equal to 1.6 times the average value, output the current balance alert signal indicating that an alert is required, and output the current balance control signal for not turning off the hot swap controller chips; and
in response to the current detection signals of each of the hot swap controller chips being greater than or equal to 0.9 times the average value and less than or equal to 1.1 times the average value, output the current balance alert signal indicating that an alert is not required, and output the current balance control signal for not turning off the hot swap controller chips.

9. The apparatus according to claim 1, wherein the controller is a baseboard management controller.

10. The apparatus according to claim 9, wherein a current detection signal pin of each of the hot swap controller chips is connected with an analog-to-digital conversion input/output pin of the baseboard management controller, and an alert signal pin of each of the hot swap controller chips is connected with an analog-to-digital conversion input/output pin of the baseboard management controller; the current detection signal pin is configured to output a current detection signal of the hot swap controller chip corresponding to the current detection signal pin, and the alert signal pin is configured to output an alert signal of the hot swap controller chip corresponding to the alert signal pin.

11. An method of processing a fault of a parallel hot swap controller chip, comprising:
connecting a plurality of hot swap controller chips in parallel, each of the hot swap controller chips having a plurality of preset fault state signals;
converting, by each of conversion circuits, the preset fault state signals into a fault alert signal, wherein the conversion circuits correspond to the hot swap controller chips on a one-to-one basis; and
analyzing, by a controller, the fault alert signal outputted by each of the conversion circuit, to determine a faulty hot swap controller chip and a fault type of the faulty hot swap controller chip.

12. The method according to claim 11, wherein the conversion circuit comprises: a first switch transistor, a second switch transistor, a third switch transistor, a fourth switch transistor, a first resistor, a second resistor, a third resistor, a fourth resistor and a pull-up resistor; resistance values of the first resistor, the second resistor, the third resistor and the fourth resistor are all different;
the first switch transistor and the first resistor are connected in series to form a first branch circuit, the second switch transistor and the second resistor are connected in series to form a second branch circuit, the third switch transistor and the third resistor are connected in series to form a third branch circuit, and the fourth switch transistor and the fourth resistor are connected in series to form a fourth branch circuit; one end of the pull-up resistor is connected to a power source, the first branch circuit, the second branch circuit, the third branch circuit and the fourth branch circuit are connected in parallel between the other end of the pull-up resistor and the ground, and the first switch transistor, the second switch transistor, the third switch transistor and the fourth switch transistor are all grounded, and the fault alert signal is a voltage value at the other end of the pull-up resistor;
the preset fault state signals comprise an over current protection signal, an over temperature protection signal, a short current protection signal and an over voltage protection signal, wherein the over current protection signal is configured to drive the first switch transistor to be turned on or off, the over temperature protection signal is configured to drive the second switch transistor to be turned on or off, the short current protection signal is configured to drive the third switch transistor to be turned on or off, and the over voltage protection signal is configured to drive the fourth switch transistor to be turned on or off; and, at most one of the first switch transistor, the second switch transistor, the third switch transistor and the fourth switch transistor is turned on at the same moment.

13. The method according to claim 12, wherein the conversion circuit comprises: a first switch transistor, a second switch transistor, a third switch transistor, a fourth switch transistor, a first resistor, a second resistor, a third resistor, a fourth resistor, a fifth resistor, a sixth resistor, a seventh resistor and a pull-up resistor; resistance values of the first resistor, the second resistor, the third resistor, the fourth resistor, the fifth resistor, the sixth resistor, the seventh resistor and the pull-up resistor are all the same;
the first switch transistor and the first resistor are connected in series to form a first branch circuit, the second switch transistor and the second resistor are connected in series to form a second branch circuit, the third switch transistor and the third resistor are connected in series to form a third branch circuit, and the fourth switch transistor and the fourth resistor are connected in series to form a fourth branch circuit; one end of the pull-up resistor is connected to a power source, the first branch circuit, the second branch circuit, the third branch circuit and the fourth branch circuit are connected in parallel between the other end of the pull-up resistor and the ground, and the first switch transistor, the second switch transistor, the third switch transistor and the fourth switch transistor are all grounded, the fifth resistor is connected in series between the first resistor and the second resistor, the sixth resistor is connected in series between the second resistor and the third resistor, the seventh resistor is connected in series between the third resistor and the fourth resistor, and the fault alert signal is a voltage value at the other end of the pull-up resistor;
the preset fault state signals comprise an over current protection signal, an over temperature protection signal, a short current protection signal and an over voltage protection signal, the over current protection signal is configured to drive the first switch transistor to be turned on or off, the over temperature protection signal is configured to drive the second switch transistor to be turned on or off, the short current protection signal is configured to drive the third switch transistor to be turned on or off, and the over voltage protection signal is configured to drive the fourth switch transistor to be turned on or off; and, at most one of the first switch transistor, the second switch transistor, the third switch transistor and the fourth switch transistor is turned on at the same moment.

14. The method according to claim 13, wherein analyzing, by the controller, the fault alert signal outputted by each conversion circuits, to determine a faulty hot swap controller chip and the fault type of the hot swap controller chip, comprises:
in response to the fault alert signal outputted by a conversion circuit and being equal to half of a power source voltage, confirming that a hot swap controller chip corresponding to the conversion circuit outputting the fault alert signal being equal to half of the power source voltage has a fault, and the fault type is over current protection of the hot swap controller chip;
in response to the fault alert signal outputted by a conversion circuit and being equal to two thirds of the power source voltage, confirming that a hot swap controller chip corresponding to the conversion circuit outputting the fault alert signal being equal to two thirds of the power source voltage has a fault, and the fault type is over temperature protection of the hot swap controller chip;
in response to the fault alert signal outputted by a conversion circuit being equal to three quarters of the power source voltage, confirming that a hot swap controller chip corresponding to the conversion circuit outputting the fault alert signal being equal to three quarters of the power source voltage has a fault, and the fault type is short current protection of the hot swap controller chip;
in response to the fault alert signal outputted by a conversion circuit and being equal to four fifths of the power source voltage, confirming that a hot swap controller chip corresponding to the conversion circuit outputting the fault alert signal being equal to four fifths of the power source voltage has a fault, and the fault type is over voltage protection of the hot swap controller chip; and
in response to the fault alert signal outputted by a conversion circuit being equal to zero, confirming that a hot swap controller chip corresponding to the conversion circuit outputting the fault alert signal being equal to zero has no fault.

15. The method according to claim 11, wherein each of the hot swap controller chips further has a current detection signal, and the controller is further configured to collect the current detection signal of each of the hot swap controller chips, process the collected current detection signal, and then generate a current balance alert signal and a current balance control signal according to a preset decision rule; and the method further comprises:
connecting a first input end of an AND gate to a power-on signal, connecting a second input end of the AND gate to the current balance control signal, and connecting an output end of the AND gate to an enable signal pin of each of the hot swap controller chips.

16. The method according to claim 15, wherein processing the collected current detection signal, and then generating the current balance alert signal and the current balance control signal according to the preset decision rule, comprise:
calculating an average value of all collected current detection signals;
in response to the current detection signal of any one of the hot swap controller chips being less than 0.6 times the average value or greater than 1.6 times the average value, outputting the current balance alert signal indicating that an alert is required, and outputting the current balance control signal for turning off the hot swap controller chips;
in response to the current detection signal of each of the hot swap controller chips being greater than or equal to 0.6 times the average value and less than or equal to 1.6 times the average value, and the current detection signal of any one of the hot swap controller chips being greater than or equal to 0.6 times the average value and less than 0.9 times the average value, outputting the current balance alert signal indicating that an alert is required, and outputting a current balance control signal for not turning off the hot swap controller chips;
in response to the current detection signal of each of the hot swap controller chips being greater than or equal to 0.6 times the average value and less than or equal to 1.6 times the average value, and the current detection signal of any one of the hot swap controller chip being greater than 1.1 times the average value and less than or equal to 1.6 times the average value, outputting the current balance alert signal indicating that an alert is required, and outputting the current balance control signal for not turning off the hot swap controller chips; and
in response to the current detection signals of each of the hot swap controller chips being greater than or equal to 0.9 times the average value and less than or equal to 1.1 times the average value, outputting the current balance alert signal indicating that an alert is not required, and outputting the current balance control signal for not turning off the hot swap controller chips.

17. The method according to claim 16, wherein calculating the average value of all collected current detection signals, comprises:
calculating the average value of all current detection signals by the following
$${I}_{a v g} = \frac{1}{n} {\sum }_{i = 0}^{n} IMONi$$
wherein IMONi is a current detection signal of an ith hot swap controller chip, and I_{avg} is an average value of all current detection signals.

18. The method according to claim 11, wherein the controller is a baseboard management controller.

19. A computer device, comprising:
at least one processor; and
a memory, wherein the memory stores a computer program which can be run in the processor, and when the processor executes the program, the method according to claim 11 is executed.

20. A computer non-transitory readable storage medium, wherein the computer non-transitory readable storage medium stores a computer program, wherein when the computer program is executed by a processor, the method according to claim 11 is executed.
